(19) United States
(12) Patent Application Publication
(10) Pub. No.: US 2018/0205343 A1
(43) Pub. Date: Jul. 19, 2018

(54) SYSTEMS AND METHODS FOR BUILDING-INTEGRATED POWER GENERATION

(71) Applicant: 1st Turning Founders LLC, Aventura, FL (US)

(72) Inventor: NESTOR G. PEREGO, AVENTURA, FL (US)

(21) Appl. No.: 15/739,594

(22) PCT Filed: Jun. 24, 2016
(86) PCT No.: PCT/US16/39284

§ 371 Date: Dec. 22, 2017

Related U.S. Application Data
(60) Provisional application No. 62/184,486, filed on Jun. 25, 2015.

(51) Int. Cl. H02S 40/32; H02S 40/38; H02S 20/23; H02S 20/26; H01L 31/053

(52) U.S. Cl. CPC H02S 40/32; H02S 40/38; H01L 31/053; H02S 20/26; H02S 20/23

(57) ABSTRACT

Systems and devices are disclosed that describe integrated roofing elements. The integrated roofing elements can feature integrated energy generation elements and energy storage elements that can both generate (e.g. photovoltaic cells, thermoelectric devices) and store energy (e.g. batteries and supercapacitors). Moreover, they can include a microinverter (for example, a three-phase microinverter) to send and receive energy to the grid. They can also include controllers for directing the generated or stored energy within each integrated roofing element, and between the integrated roofing element and the grid and/or various alternating current (AC) and direct current (DC) loads. Moreover, the integrated roofing elements can be connected to form a roof not requiring continuous solid support beneath each integrated roofing element.

### CROSS-REFERENCE TO RELATED APPLICATIONS

This application claims benefit of U.S. Provisional Application No. 62/184,486, filed Jun. 25, 2015, which is hereby incorporated herein by reference in its entirety.

### BACKGROUND

Increasing environmental concerns have led to interest in renewable energy technologies. Today, photovoltaic installations on commercial and residential roofs can be viable alternative energy sources. Existing photovoltaic installations generally include an array of photovoltaic modules that can be affixed to an existing roof structure. These photovoltaic structures have certain advantages. For example, they are generally compatible with a wide variety of existing roof structures. However, these systems require separate superstructures to support the photovoltaic panels. As these superstructures are generally customized for a given installation, these systems can be complex to design, manufacture, and install. In addition, because of the additional weight of the photovoltaic modules and superstructure, costly structural upgrades to the building can be required to support the photovoltaic installation. Further, because of the need in conventional photovoltaic systems to first build a roof or other structural components and then add photovoltaic panels to the completed roof, it is a costly process not only in terms of financial expense but also in time required to complete the system.

Building-integrated photovoltaics (BIPVs) have been explored as an improved strategy for incorporating photovoltaics into buildings. BIPVs are photovoltaic materials that can be used to replace conventional building materials in parts of the building envelope, such as the roof, skylights, or facades. BIPVs can interface with current roof coverings such as tiles, slates and metal roofing.

While attractive in principle, existing BIPV systems suffer significant drawbacks that have hampered their widespread adoption. For example, to replace conventional building materials, BIPVs would need to meet an end user's specifications regarding durability and reliability prior to adoption. Thus far, existing BIPVs have failed to possess sufficient durability and reliability to replace conventional building materials in most applications. Furthermore, other issues, such as water penetration, islanding and heat transfer due to poor design integration considerations, and difficult maintenance procedures have contributed to the low uptake rates of BIPV systems.

It may be desirable for integrated renewable energy roofing elements to have similar or better insulating and aesthetic specifications than ordinary roof tiles. However, this may not feasible unless the roof structure is reconfigured in order to support the embedded system. This issue can occur in building renovations when the designed structural loading capacity cannot support the weight of BIPV modules. Existing BIPV modules can be heavy. Consequently many buildings, especially those undergoing renewal may have not been designed to support this additional weight. Failure of the structure to support BIPV modules may result in the collapse of buildings.

Additionally, buildings should be able to hold live loads on BIPV such as snow, ice and wind. A lack of allowance for extra loads can cause energy generation devices such as photovoltaic modules to bend and/or shatter and result in the need for serious repairs or replacement. Further if they have not been designed to move and absorb these loads, the BIPV modules can become detached from building envelopes and cause a risk to the public and occupants within the building.

Another problem with conventional roof-mounted energy generation devices such as photovoltaic panel arrays can be their limited ability to endure outside environmental conditions. Roof-mounted photovoltaic panels can often be damaged by adverse weather conditions, thus increasing the frequency with which they may need to be replaced and therefore the cost of maintaining the roof-mounted array. Wind-driven rain effects can be accelerated rain drops which penetrate construction products at joints, overlaps, and the like through the ingress of water. Water tightness with BIPV systems can be technical barrier during construction. Water ingress can also include condensation created by humidity. This can lead to corrosion, reducing the life of the system and its parts.

Cabling and connection issues can be problematic with BIPV systems as modules on either a roof or facade should be interconnected and linked back to the inverter that transforms direct current into alternating current (AC). Inefficiencies of wiring used to install BIPV systems can cause parts of the radiation that hit the photovoltaic module surface to be lost. The effect of power loss through wiring may have the ability to reduce the overall performance of the system and may also pose a maintenance issue if cabling issues occur post-installation.

Further, the performance of a BIPV system needs to be constantly monitored to ensure any fault is identified throughout its lifespan and rectified. However, a lack of fault alert systems being installed with BIPV systems is widespread.

Moreover, many renewable energy sources (i.e. solar, wind, thermal, and the like) may be considered intermittent energy sources. An intermittent energy source can be any source of energy that is not continuously available due to some factor outside direct control. For example, in the absence of an energy storage system, solar photovoltaic systems do not produce power at night. The intermittent source may, in some cases, be relatively predictable, but cannot be dispatched to meet the demand of a power system. Many existing systems suffer from not adequately managing the energy generated by an intermittent energy source.

Therefore, what are needed are devices, systems and methods that overcome challenges of existing systems, some of which are described above.

### SUMMARY

Aspects of this disclosure are directed to devices and systems relating to integrated roofing elements. The integrated roofing elements can be modular and pre-fabricated. The integrated roofing elements feature integrated energy generation elements and energy storage elements that can generate (e.g. photovoltaic cells, thermoelectric devices) and store energy (e.g. batteries and supercapacitors). Moreover, they can include a microinverter (for example, a three-phase microinverter) to convert direct current (DC) energy to alternating current (AC) energy where it can be supplied to an AC electrical grid or other AC loads. Optionally, the integrated roofing elements can include a bi-directional microinverter that can operate to both (1) convert direct current (DC) energy to alternating current (AC) energy where it can be supplied to an AC electrical grid or other AC loads; and (2) receive AC energy from the grid and convert the AC energy into DC energy that can be used to charge energy storage elements and/or supply DC loads. Optionally in other embodiments, the integrated roofing elements can include a rectifier such that AC energy can be received from the grid and converted into DC energy that can be used to charge energy storage elements and/or supply DC loads.

The integrated roofing elements can also include controllers for directing the generated or stored energy within each integrated roofing element, and between the integrated roofing element and the grid and/or various AC and DC loads. This can be based on exogenous variables such as load amount, usage, environmental conditions, real-time local weather conditions, utility tariffs and the like.

Moreover, the integrated roofing elements can be connected to form a roof not requiring continuous solid support beneath each integrated roofing element. Furthermore, they can be easier to install as compared with existing rooftop energy generation modules and traditional BIPVs, leading to reduced installation cost, time and space. Any one of the integrated roofing elements can be at least partially dismounted and reinstalled without physical or operational interference with existing integrated roofing elements. The integrated roofing elements can, for example, be readily installable on a conventional truss and purlin roof structural supports. They can moreover be mounted on roof structural support without restriction on the gradient of the roof. Furthermore in another aspect, the integrated roofing elements features seals that can serve as watertight seals between elements.

In various aspects of this disclosure, an integrated roofing element is described. The integrated roofing element can include: an energy generation element; a microinverter; an energy storage element; an integrated roofing element controller; electrical wiring and connections; and a structural component.

The structural component can provide sufficient strength to the integrated roofing element such that one or more integrated roofing elements can span between support elements of a roof without continuous solid support beneath each integrated roofing element. Moreover, the energy generation device can be electrically connected to the microinverter, the energy storage element can be electrically connected to the microinverter through the integrated roofing element controller and the microinverter can be connected to the electrical wiring. The electrical connections can include industrial and multiphase power plugs and sockets.

The energy generation element can be any suitable component that can locally generate electrical energy. Examples of such components include, for example, photovoltaic cells, diesel generators, wind turbines, thermoelectric devices, piezoelectric devices, and fuel cells. In some embodiments, the energy generation element can generate renewable energy. In some embodiments, the energy generation element can generate energy in variable amounts depending on local environmental conditions (e.g., time of day, weather, etc.). For example, in certain embodiments, the energy generation element can be a photovoltaic cells or a thermoelectric device. The energy generation element can furthermore include graphene photovoltaic cells. The integrated roofing element controller can be controlled by a system controller. The electrical connections can be configured to electrically connect a first integrated roofing element to a second integrated roofing element.

The energy storage element can include a battery. The energy storage element can include a supercapacitor. The supercapacitor can include a double-layer capacitor, a pseudocapacitor, or a hybrid capacitor.

The microinverter can include a single-phase microinverter. The microinverter can be a polyphase microinverter, for example, the microinverter can include a three-phase microinverter. The microinverter can optionally be a bi-directional microinverter.

The integrated roofing elements can include a rectifier. The rectifier can be electrically connected to the electrical wiring and connections. The rectifier can also be electrically connected to the energy storage element through the integrated roofing element controller.

The integrated roofing element can further include seals such that a weather-tight seal can be formed when two integrated roofing elements are connected. The structural component can include a frame that substantially encompasses the energy generation device, the microinverter, the energy storage element, the integrated roofing element controller, and the electrical wiring and connections.

The roof can be a low-slope roof. Moreover, the roof can include: a flat roof, shed roof, pitched roof with catslide, saw-tooth roof, gable roof, butterfly roof, mansard roof, clerestory roof, gable or saddle roof, trough gambrel roof, clerestory roof hip roof, half-hip roof, tented roof, gablet roof, hip roof, half-hip roof, tented or pavilion roof, Dutch gable roof, rhombic roof, rainbow roof, barrel roof, bow roof, or conical roof.

In various aspects of this disclosure, a system is described. The system can include an integrated roofing element. The integrated roofing element can include an energy generation device; a microinverter; an energy storage element; an integrated roofing element controller; electrical wiring and connections; and a structural component, wherein the structural component provides sufficient strength to the integrated roofing element such that one or more integrated roofing elements can span between support elements of a roof without continuous solid support beneath each integrated roofing element. The system can furthermore include a system controller, and a roof assembly structural component. The roof assembly structural component can provide mechanical support to two or more integrated roofing elements in physical proximity to one or more walls of a building.

The energy generation device can be electrically connected to the microinverter, the energy storage element can be electrically connected to the microinverter through the integrated roofing element controller and the microinverter can be connected to the electrical wiring. The integrated roofing element controller can be controlled by the system controller. The electrical connections can include industrial and multiphase power plugs and sockets. Moreover, when the integrated roofing elements are assembled, they form a roof of the building.

The energy generation element can include any one of a photovoltaic cell, diesel generator, wind turbine, thermoelectric device, piezoelectric device, and fuel cell. The integrated roofing element controller can be controlled by a system controller. The electrical connections can be configured to electrically connect a first integrated roofing element to a second integrated roofing element. The energy generation device can include graphene photovoltaic cells. The energy generation device can include graphene photovoltaic cells.

The energy storage element can include a battery. The energy storage element can include a supercapacitor. The supercapacitor can include a double-layer capacitor, a pseudocapacitor, or a hybrid capacitor.

The microinverter can include a single-phase microinverter. The microinverter can be a polyphase microinverter, for example, the microinverter can include a three-phase microinverter. The microinverter can optionally be a bi-directional microinverter.

The integrated roofing elements can include a rectifier. The rectifier can be electrically connected to the electrical wiring and connections. The rectifier can also be electrically connected to the energy storage element through the integrated roofing element controller.

The building can include commercial or residential buildings. Any one of the integrated roofing elements can be dismounted and reinstalled without physical or operational interference with existing integrated roofing elements.

The roof can include a low-slope roof. The roof assembly structural component can be able to support both dynamic and static loads. The roof can include a flat roof, shed roof, pitched roof with catslide, saw-tooth roof, gable roof, butterfly roof, mansard roof, clerestory roof, gable or saddle roof, trough gambrel roof, clerestory roof hip roof, half-hip roof, tented roof, gablet roof, hip roof, half-hip roof, tented or pavilion roof, gablet roof, dutch gable roof, rhombic roof, rainbow roof, barrel roof, bow roof, or conical roof.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF THE DRAWINGS

The components in the drawings are not necessarily to scale relative to each other and like reference numerals designate corresponding parts throughout the several views:

FIG. 1 shows a schematic of integrated roofing elements arranged in an array.

FIG. 2 shows an assembly of the integrated roofing elements described in FIG. 1, moreover showing the electrical connection of the integrated roofing elements to each other and the grid.

FIG. 3 shows an example of an individual integrated roofing element.

FIG. 4 shows an example embodiment of an integrated roofing element electrically incorporated into a building and the grid.

FIG. 5 shows some aspects of an example implementation of the integrated roofing element into a roof.

FIG. 6 illustrates an example of an individual integrated roofing element that includes a thermal regulation element. In this case, the integrated roofing element includes a passive thermal regulation element (i.e., an air gap separating the photovoltaic cell and a battery and microinverter).

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of preferred embodiments and the Examples included therein and to the Figures and their previous and following description.

Aspects of the disclosure are directed to integrated roofing elements that combines roofing elements, energy generation elements, energy storage elements, microinverters, controllers, and related peripherals into a single, installable structure that can be interlocked to form a roof. This can provide cost savings, for example, in the construction cost of roofs and photovoltaic systems. It can reduce excess materials and labor that go into first building a roof only to later add these additional energy generation elements on top of the roof.

Existing rooftop energy generation may require an energy generation element, energy storage element, inverters, controllers, cabling and roof mounting structures. These parts may be sold separately by different vendors, leading to “soft” costs for the rooftop system. In one aspect of the disclosure, a modular, pre-fabricated, integrated roofing element is disclosed, combining an energy storage element (comprising, for example, a battery or a supercapacitor), an energy generation element (comprising for example, a photovoltaic cells and thermoelectric devices), a microinverter (comprising for example, a three-phase microinverter), a structural element, and a controller unit for directing the generated or stored power based on exogenous variables such as load, usage, environmental conditions, and the like. The structural component can provide sufficient strength to the integrated roofing element such that one or more integrated roofing elements can span between support elements of a roof (e.g., trusses, rafters or purlins) without continuous solid support beneath each integrated roofing element.

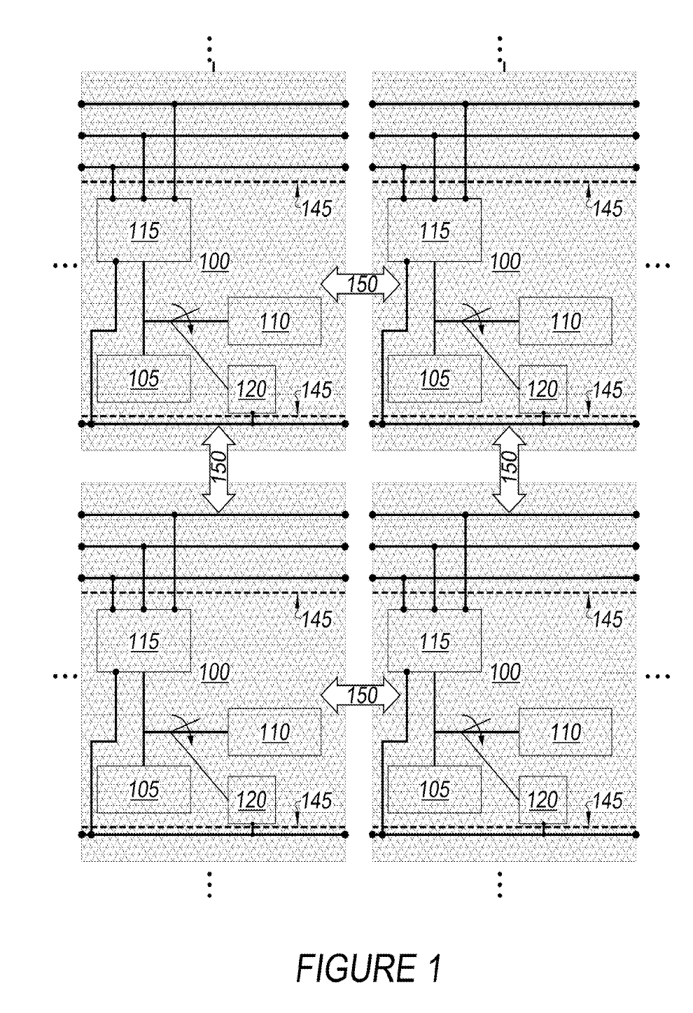

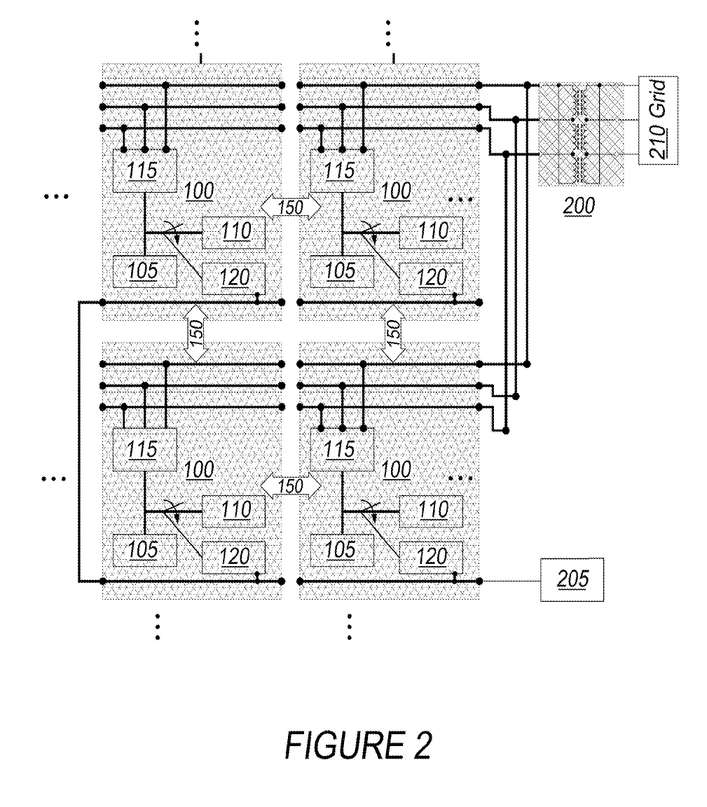

FIG. 1 shows a schematic of integrated roofing elements 100 arranged in an array. Each integrated roofing element 100 can comprise an energy generation element 105, and an energy storage element 110, e.g. a battery, supercapacitor, or the like. The energy storage element 110 can be electrically connected to a microinverter 115 through the use of a roofing element controller 120, which can control the level of power flowing to the microinverter 115 from the energy generation element or the energy storage element. For example, the roofing element controller 120 can control a switch that allows power to flow from the energy storage element 110 through the microinverter 115. The microinverter 115 can be a single phase (not shown) or a polyphase microinverter. A three-phase microinverter 115 is shown in FIG. 1, represented by the three connections emanating from 115. Individual roofing elements can be electrically connected to one another through electrical connections, represented by 150. The electrical connections 150 can connect the outputs of the microinverters together and the roofing element controllers 120 together. The roofing element controllers 120 can be controlled by a system controller, as will be described in FIG. 2. There can additionally be structural elements (not shown), such as seals, that provide environmental protection (e.g. against water, for example), and provide support in integrating the integrated roofing elements to one another and to the walls of a building. Moreover, in one aspect all or a portion of one integrated roofing element can be dismounted and reinstalled without physical or operational interference with existing integrated roofing elements. For example, a portion of a single integrated roofing element 100 can be removed for maintenance or replacement without breaking electrical continuity with other integrated roofing elements 100. In particular the portions within the region demarcated by dashed lines 145 represent an example portion that can be removed from an integrated roofing element without breaking electrical continuity between neighboring integrated roofing elements.

The energy generation element 105 can include a photovoltaic cell, diesel generator, wind turbine, thermoelectric device, piezoelectric device, a fuel cell and the like and combinations thereof. The photovoltaic cell may comprise any suitable element configured to convert incident solar energy into DC electricity. For example, in certain embodiments, the photovoltaic cell may comprise a graphene photovoltaic cell. Moreover, the graphene photovoltaic cells can be semi-transparent—for example, allowing installations in windows, significantly increasing the available area of a hi-rise building for solar generation—flexible and non-toxic.

In one aspect, the energy storage element 110 can comprise a battery. The battery can be, for example, a lithium-ion battery.

Thus in another aspect of the disclosure, the energy storage element 110 can comprise a supercapacitor. The supercapacitor can be a double-layer capacitor, where for example, the charge is stored electrostatically (i.e. in a Helmholtz layer), a pseudocapacitor, where the charge is stored electrochemically (i.e. Faradaic charge transfer), or a hybrid capacitor. Moreover, the double layer capacitor can comprise activated carbons, carbon nanotubes (CNTs), graphene, carbide-derived carbon (CDC) or carbon aerogels. The pseudocapacitor can comprise conducting polymers or metal oxides. The hybrid capacitor can comprise capacitors having asymmetric electrodes, where the charge storage can be a combination of electrostatic and electrochemical storage. The hybrid capacitor can furthermore comprise asymmetric pseudocapacitor/electrical double-layer capacitor (EDLC) type hybrids, composite hybrids, or rechargeable battery-type hybrids.

Moreover the supercapacitor can comprise a mediator solid-state supercapacitor. The mediator component of the supercapacitor can be integrated into the solid electrolyte. The mediator may improve the characteristics of the solid-state supercapacitor, allowing it to compete with lithium-ion batteries in gravimetric and volumetric energy density, while keeping the supercapacitor's ability to fast charge, lower manufacturing cost and extended lifespan.

The microinverter 115 can be used to convert DC into AC to power loads and feed the electricity into the electric grid. Historically, the DC output of several photovoltaic cells was combined and fed into one large inverter (called string or central inverter). One problem with a single inverter system may be that all interconnected panels need to perform at identical levels. One malfunctioning panel—or partial shading—can bring down the energy generation of the entire string. Other problems may include: single point of failure, the required high-voltage DC wiring being dangerous and expensive.

By incorporating microinverters 115 into the integrated roofing elements, each integrated roofing element can produce energy independently of other integrated roofing elements; thus, eliminating the possibility that a single point failure will disable the entire system. Additionally, the microinverters can have a low internal temperature rise and a long lifetime. They can also reduce the space, heat, noise and visual concerns with large string inverter systems. Furthermore, they can be easy to install and dramatically reduced installation cost, time and space.

Moreover, the microinverter 115 can be polyphase such as a three-phase microinverter. Many existing microinverters are single-phase microinverters. Utilities generally distribute electricity in a three-phase configuration and only switch to single-phase at the single-family home level. Therefore, existing single-phase microinverters may present shortcomings for medium-size installations when forced into a three-phase configuration to power a building and connect to the grid. These shortcomings can include: imbalances among the three phases, expensive wiring and a reduced lifespan compared to the lifespan of photovoltaic panels. Moreover, single-phase microinverters may not be amenable to being efficiently built inside of an integrated roofing element for three-phase installations. As further described in relation to FIG. 2, the microinverter can also be used to control phase synchronization when there are multiple panels connected in a polyphase system.

FIG. 2 shows a system comprising the integrated roofing elements described in relation to FIG. 1. In particular, FIG. 2 shows the electrical connection of an array of the integrated roofing elements 100 to each other and to an electrical grid 210. Optionally, the array of the integrated roofing elements 100 can be directly connected to a load (not shown) that is isolated from the grid 210. Specifically, each roofing element controller 120 can be connected to one another and to a system controller 205 that manages the generated power distribution between the energy generation elements 105, the energy storage elements 110, the microinverters 115, and the grid 210 or other load (not shown). Generally, the array of the integrated roofing elements 100 will be connected to the grid 210 through a transformer 200. Generally, the transformer 200 will be used to step up voltage from the array of the integrated roofing elements 100 to the nominal voltage level of the grid 210, or to step down voltage from the grid 210 to the voltage level of the interconnected array of the integrated roofing elements 100.

For example, during one time period, the energy generation element 105 can be used to charge the energy storage element 110. At another time period, the energy storage element 110 can provide energy to the grid (for example, through the transformer 200) or to lower voltage AC loads (after the microinverter 115) or DC loads (before the microinverter 115) directly (not shown). At still other times, the energy generation element 105 and the energy storage element 110 can simultaneously provide energy to the grid and/or to AC or DC loads directly. Moreover, energy can flow between the energy generation element 105, the energy storage element 110, and the grid 210 (if connected). For example, DC energy created by the energy generation element 105 or that has been stored in the energy storage element 110 can be converted to AC energy by the microinverter 115, carried to the transformer 200 by the electrical wiring and connections 150, stepped up to the nominal grid voltage by the transformer 200, and then provided to the grid 210. Similarly, energy can flow from the grid 210, through the transformer 200 (where voltage will generally be stepped down), and through a rectifier (not shown) where it can be used to charge the energy storage element 110. In one aspect, the rectifier can be integrated with and into the microinverter 115 (e.g., the microinverter can be a bi-directional microinverter). In another aspect, the rectifier can be a separate device. In one aspect, each integrated roofing element 100 has a dedicated rectifier. In another aspect, more than one integrated roofing element 100 of an array of integrated roofing elements 100 can share a rectifier.

As mentioned, the microinverters 115 of the roofing elements 100 can be connected to the grid 210 through the electrical wiring and connections 150 and a transformer 200. For the case of the three-phase power supply, electrical connections can be made to a three-phase power transformer. Further, as noted herein, a system controller 205 can be used to control each individual integrated roofing element 100 and the interconnected array of integrated roofing elements 100. For example, the system controller 205 can be connected with the roofing element controller 120 and microinverter 115 of each integrated roofing element 100. Generally, this will be through a wired connection (including fiber optic cable), but it is also contemplated that wireless communication can be used for control purposes. The system controller 205 in cooperation with the roofing element controller 120 and microinverter 115 of each integrated roofing element 100 can be used to charge the energy storage element 110, cause power to flow from the energy storage element 110 to the microinverter 115, control the output voltage and/or current of the microinverter 115, turn the microinverter 115 on or off, control the phase angle of each phase of the microinverter 115 if the microinverter is a polyphase microinverter (which can include separate single-phase microinverters for each phase of a polyphase system), and the like. Further, while not shown in FIG. 2, the system controller 205 can be used to control the transformer 200, switching mechanisms (not shown), metering (not shown), and the like to connect the array of integrated roofing elements 100 to the grid 210 including, for example, controlling the voltage levels of the transformer 210 and phase synchronization of the array of integrated roofing elements 100 with the grid 210.

In some embodiments, system controller 205 can be configured to overcoming existing problems with anti-islanding in photovoltaic systems. Generally, when photovoltaic systems are connected to the grid, the photovoltaic systems are equipped with an anti-islanding function that halts electricity generation from the photovoltaic panels if and when the electric grid goes down. Power generation is halted to ensure that no electricity generated by the photovoltaic panels enters the grid where it might cause injury to individuals trying to restore the electrical grid and/or harm systems connected to the grid. However, such anti-islanding measures prevent many existing photovoltaic systems from providing power to a building at times when the grid goes down. To overcome this problem, system controller 205 can be configured to assess the state of grid 210, directing the system to function in conjunction with grid 210 (i.e., in a grid-connected mode) when the grid is powered and to separate itself from grid 210 (i.e., operate in a off-grid mode) when the grid is down. By separating the system from the grid, the roofing elements can continue to provide electrical power to the local building(s) during periods of time when the grid is down. In these cases, the microinverters can be configured to sync their frequency to the grid's frequency when the system is operating in a grid-connected mode, and to produce their own alternating sine wave when the system is operating in an off-grid mode.

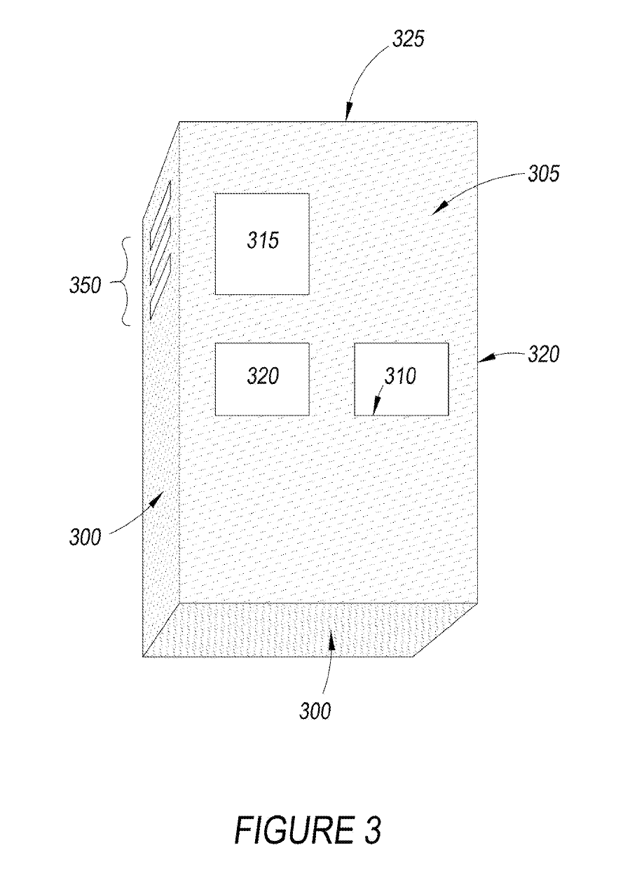

FIG. 3 shows an example of an individual integrated roofing element 325. The integrated roofing element 325 can comprise an energy generation element 305. The energy generation element 305 can comprise a photovoltaic cell, diesel generator, wind turbine, thermoelectric device, piezoelectric device, a fuel cell, or the like, as described in relation to FIG. 1. In one aspect, the photovoltaic cell(s) can be positioned on one face of the integrated roofing element 325. The face can be an exterior face that can be exposed to sunlight, for example. The integrated roofing element 325 can further comprise a microinverter 315, as also described in relation to FIGS. 1 and 2. The microinverter 315 can comprise a single phase microinverter or a polyphase microinverter such as a three-phase microinverter. The integrated roofing element 325 can further comprise an energy storage element 310. The energy storage element 310 can comprise a battery, a supercapacitor, and the like, as described in relation to FIG. 1. The integrated roofing element 325 can further comprise a roofing element controller 320.

In some embodiments, the integrated roofing element can further include thermal regulation elements to control the temperature of energy generation element 305 (e.g., the photovoltaic cell(s)), energy storage element 310 (e.g., the battery), and/or other electrical components of the integrated roofing element. By way of example, in the case of an integrated roofing element that includes a photovoltaic cell and a battery, depending on the daily temperature and other factors, the photovoltaic cell may overheat the battery and vice-versa, causing both components to underperform as their best performance is within a certain temperature range. A thermal regulation element can be included to regulate the temperature of one or more components of the integrated roofing elements to improve performance. Examples of suitable thermal regulation elements are well known in the art and can be selected in view of a variety of performance considerations. For example, the thermal regulation element can be a passive thermal regulation element, an active thermal regulation element, or a combination thereof. Passive thermal regulation elements include, for example, air gaps positioned between components of the integrated roofing element, insulators positioned between components of the integrated roofing element, heat sinks positioned adjacent to one or more components of the integrated roofing element, phase change materials positioned adjacent to one or more components of the integrated roofing element, or a combination thereof. Active thermal regulation elements include, for example, forced circulating air passed between one or more components of the integrated roofing element, water/refrigerant circulating between one or more components of the integrated roofing element, or a combination thereof. In embodiments where water is circulated between one or more components of the integrated roofing element (e.g., between a photovoltaic cell and a battery), the circulating water, once heated by the components of the integrated roofing element (e.g., by the photovoltaic cell and/or battery), can be used as hot water in local building(s). In embodiments where a refrigerant is circulated between one or more components of the integrated roofing element (e.g., between a photovoltaic cell and a battery), the refrigerant can be used in combination with the local building's AC units (e.g., in their heat transfer systems). Thermal regulation elements can also be used to heat components of the integrated roofing element (e.g., a photovoltaic cell, battery, etc.) in cold climates to improve system performance. As an example, in cold climates, water, air, or another suitable fluid can be circulated between one or more components of the integrated roofing element (e.g., between a photovoltaic cell and a battery) to warm the components to raise their temperature to a more preferable performing range. Water, air, or another suitable fluid can also be circulated with an integrated roofing element to warm a photovoltaic cell to melt snow and ice deposited on the active surface of the photovoltaic cell.

As mentioned in the context of FIG. 2, the roofing element controller 320 can control the distribution of power generated from the energy generation element 305 and the energy produced by the energy storage element 310. For example, at one time period, the energy generation element 305 can charge the energy storage element 310. At another time, the energy storage element 310 can provide energy to the grid or to AC or DC loads directly (not shown). At still other times, the energy generation element 305 and the energy storage element 310 can simultaneous provide energy to the grid and/or AC or DC loads directly. Moreover, energy can flow between the energy generation element 305, the energy storage element 310, and the grid.

In one aspect of the disclosure, the integrated roofing elements 325 can be electrically connected to one another at one or more electrical connections 350. These electrical connections can comprise industrial and multiphase power plugs and sockets.

In another aspect, the integrated roofing elements 325 can be mechanically connected to one another to form a roof, through one or more structural components 300. The structural component can provide sufficient strength to the integrated roofing element such that one or more integrated roofing elements can span between support elements of a roof without continuous solid support beneath each integrated roofing element. In some aspects, the structural component can comprise a frame that substantially encompasses the energy generation element 305, the microinverter 315, the energy storage element 310, the integrated roofing element controller 320, and the electrical wiring and connections. Moreover, the structural components 300 can comprise any of a wide variety of mechanical securement devices and assemblies, including nails, screws, cleats, clips, and bolts, may be used to secure various components of a roof assembly. The roof assembly can comprise an assembly of interacting roof components (includes the roof deck, insulation, and roof covering). The integrated roofing elements can be operationally connected, for example, to purlins, comprising horizontal secondary structural members that transfers loads from the primary structural framing. The integrated roofing elements can moreover be operationally connected, for example, to rafters. Rafters can comprise one of a series of sloped structural members that extend from the ridge or hip to the downslope perimeter or eave, designed to support the roof deck and its associated loads. Any one of the integrated roofing elements can be dismounted and reinstalled without physical or operational interference with existing integrated roofing elements.

The roof comprising integrated roofing elements can safely supporting the design dead and live loads, including the weight of the roof systems, and the additional live loads required by the governing building codes. Moreover, the roof can support dynamic loads comprising any load which is non-static, such as a wind load or a moving live load.

The integrated roofing elements can further can include seals 300 such that a weather-tight seal can be formed when two integrated roofing elements are connected. Moreover, the seals 300 can be used as flashing to weatherproof or seal the roof system edges at perimeters, penetrations, walls, expansion joints, valley, drains, and other places where the roof covering is interrupted or terminated. Moreover, a membrane can be employed for weatherproofing. The membrane can comprise a flexible or semi-flexible material, which functions as the waterproofing component in a roofing or waterproofing assembly. Moreover, base flashing and/or membrane base flashing can be employed to close-off and/or seal a roof at the roof-to-vertical intersections, such as at a roof-to-wall juncture. Furthermore a coating of a layer of material can be applied to spread over a surface for protection. The coating can comprise liquids, semi-liquids, or mastics; spray, roller, or brush applied. Moreover, the coating can be cured to an elastomeric consistency.

Moreover, one or more snap-fit connections can be used to both mechanically and/or electrically connect one integrated roofing element to another. These snap-fit connections can be just as strong as fastened connections and can replace nuts, screws, washers, and the like. No other adhesives, solvents, or fastening processes are needed. The snap-fitting can be designed so as not to interfere with any structural elements of the integrating roofing elements and/or systems thereof. For example, the snap-fitting can be designed to integrate and not obstruct any operational aspect of the seals.

In one aspect, the integrated roofing elements 325 can be structurally linked to one another to form a roof through one or more roof assembly structural component 300. The roof assembly structural component can provide mechanical support to two or more integrated roofing elements in physical proximity to one or more walls of a building. Moreover the building comprises a commercial or industrial building, or a residential building.

In one aspect, the integrated roofing elements 325 can be structurally linked to one another to form a low or steep-sloped roof. Low sloped roofs can refer to a roof with a slope less than or equal to approximately 2 inches of rise to approximately 4 inches of rise over approximately 12 inches of run. Steep sloped roofs can comprise roofs having slopes higher than approximately 4 inches of rise over approximately 12 inches of run. Moreover, the roof can comprise, for example, a flat roof, shed roof, pitched roof with catslide, saw-tooth roof, gable roof, butterfly roof, mansard roof, clerestory roof, gable or saddle roof, trough gambrel roof, clerestory roof hip roof, half-hip roof, tented roof, gablet roof, hip roof, half-hip roof, tented or pavilion roof, gablet roof, Dutch gable roof, rhombic roof, rainbow roof, barrel roof, bow roof, or conical roof.

### Examples

The steps, processes and devices described below are to provide a non-limiting examples of applications of an exemplary integrated roofing element and systems employing integrated roofing elements as described herein. It is to be appreciated that these are only one exemplary applications of the disclosed technology and are not to be limiting in scope or embodiments.

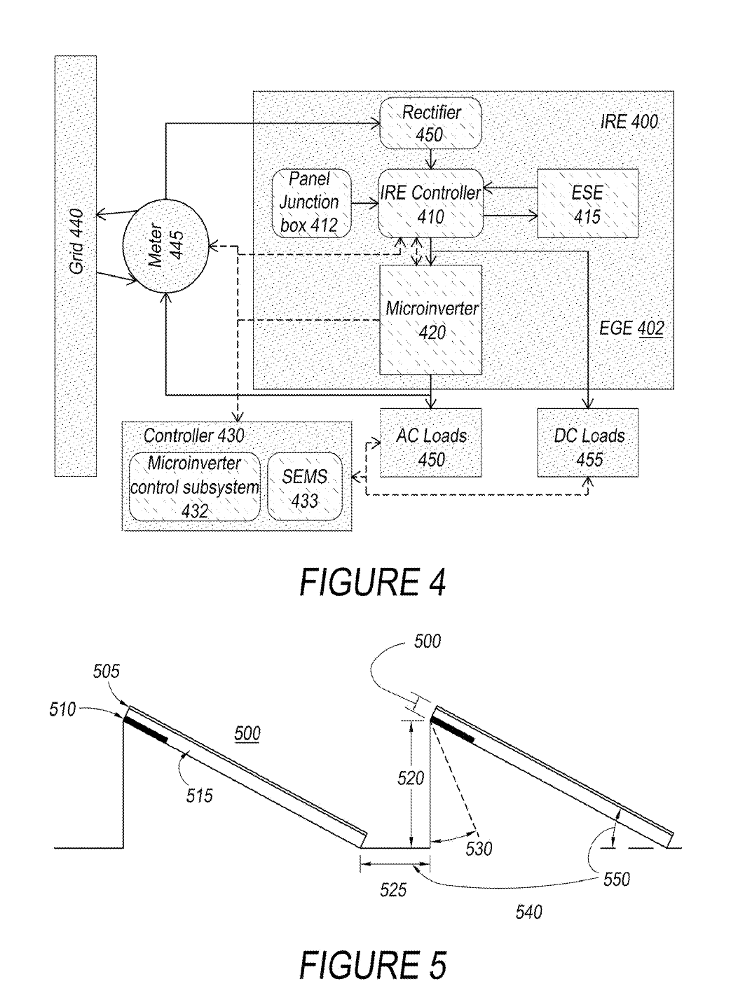

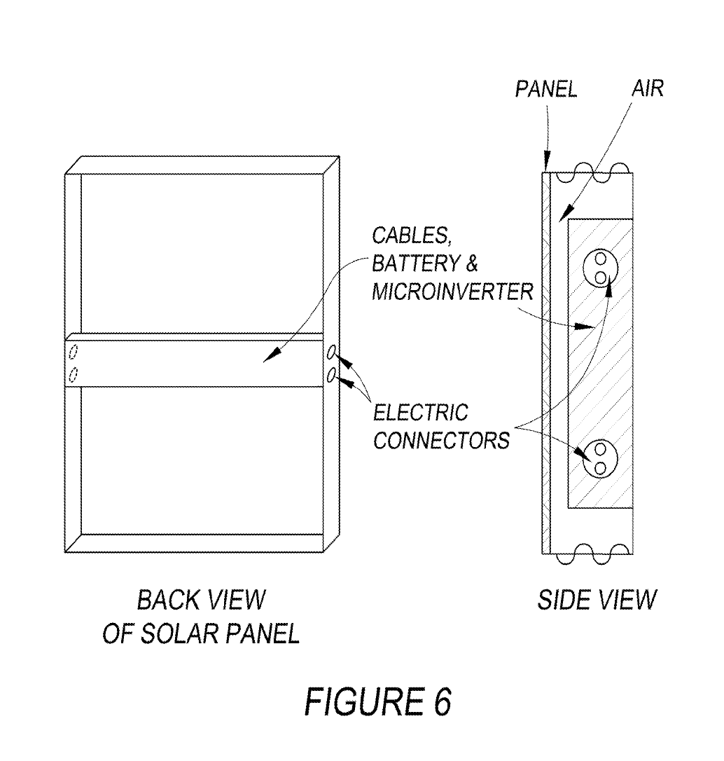

FIG. 4 shows an example embodiment of an integrated roofing element (“IRE”) electrically and structurally incorporated into a building and the grid 440. The integrated roofing element 400 has an energy generation element 402. The integrated roofing element 400 with the energy generation element 402 can provide power to local AC loads 450 and DC loads 455, such as for residential and commercial appliances (not shown). The integrated roofing element 400 with the energy generation element 402 can also provide power to the grid 440. Power supplied to or received from the grid 440 can be measured using, for example, a meter 445. An integrated roofing element controller 410 (“IRE controller”) can control the power generation/storage distribution between the energy generation element 400 and an energy storage element 415. The IRE controller 410 can be electrically connected to a microinverter 420. The microinverter 420 can be electrically connected to local AC loads 450, but not necessarily to DC loads 455. Alternatively or optionally, the integrated roofing element 400 can include a panel junction box 412, which can provide location for wiring the integrated roofing elements 400 together and providing a connection to the grid. Wiring connections in the panel junction box 412 may also include control wiring for the IRE controller 410. A system controller 430 can serve to control more than one IRE controller 410. It can comprise a microinverter control subsystem 432 to control the microinverter 420. It can additionally comprise a Smart Energy Management System (SEMS) 433 to monitor and manage the energy usage of the AC loads 450 and the DC loads 455. SEMS can allow a customer to manage their energy consumption and reduce their energy cost. This can be accomplished by managing the energy consumption according to energy price, load schedule, available energy resources, load priorities, and the like. The SEMS can furthermore use artificial intelligence to learn the load use patterns, forecast future load and price which will assist in better decision making and scheduling of loads and energy use. Moreover, the system controller 430 can communicate with the meter 445 and other grid interface devices to measure and control the flow of energy between the grid 440 and the integrated roofing element 400. The grid 440 can either provide or receive generated or stored power from the energy generation element 400 or the energy storage element 415. For example, during periods when the energy generation element 400 is able to provide more energy that is used in the AC and DC loads 450 and 455 and/or to provide energy to the energy storage element 415, it may sell the extra energy to the grid 440. The energy sold may be quantified by using the meter 445. If the energy is flowing from the grid back to the integrated roofing element 400, an additional rectifier 450 may be incorporated into the integrated roofing element. The rectifier can convert the AC of the grid to direct current (DC). In a related embodiment, the microinverter 420 can be a bi-directional microinverter that can operate to both (1) convert direct current (DC) energy to alternating current (AC) energy where it can be supplied to an AC electrical grid or other AC loads; and (2) receive AC energy from the grid and convert the AC energy into DC energy that can be used to charge energy storage elements and/or supply DC loads. In these embodiments, rectifier 450 can be absent, and the system controller 430 can control the operation of the bi-directional microinverter to select an appropriate mode of operation.

In one aspect, the microinverter 420 can employ a soft switching technique to achieve high power conversion efficiency and a phase skipping control to mitigate the light load efficiency problem. Phase skipping is a control technique to compensate for unbalancing between a plurality of phases (e.g., three phases) introduced due to selective injection of three-phase power. The control technique has two levels of operation, normal control where all phases inject power, and phase skipping control where at least one phase does not inject power. The operating mode can be determined by determining the total power available from the energy storage element(s) and/or the energy generation element(s) 400, and applying control signals to the control inputs of the microinverter 420 configured to implement phase skipping of at least one of the phases. The technique of soft-switching can be that as described in U.S. patent application Ser. No. 14/471,961, U.S. Patent Application Publication No. 2015/0062988, filed Aug. 28, 2014, “HYBRID ZERO-VOLTAGE SWITCHING (ZVS) CONTROL FOR POWER INVERTERS,” which is fully incorporated by reference and made a part hereof. Other features of the microinverter 420 can include: a longer lifespan, a higher reliability, low manufacturing cost, higher power density, inexpensive wiring and shorter installation time.

In one embodiment, optional elements can connect the controllers 410 and 430 to different types of AC and DC loads 450 and 455, such as appliances including air conditioners, lighting and refrigerators. This can allow for sequencing consumption and reducing peak-demand charges. Moreover, the controllers 410 and 430 can integrated with a mobile app, i.e. computer program designed to run on mobile devices including, but not limited to, smartphones as tablet computers. Moreover, the app can be a “native” app or “web app”. A native app can be for example, an app that may be downloadable or may come pre-packaged with hardware or an operating system. It can comprise a software application specially designed to execute on a particular device. Functionality may also be provided via what may be known as a “web app”, which is not a piece of downloadable software, but actually a web site that is optimized for viewing, for example, on a particular mobile device, such as an iPhone®. The mobile app can give the end user full, remote control over the system's operation and performance. For example, the customer can define the consumption priorities and operating conditions for each appliance. Remote monitoring and configuration of the controllers' system can be performed at a remote monitoring station. This can ensure proper operation and optimal savings; and allow automatic software updates. The remote monitoring and configuration can be performed partially or fully, for example, by using Industrial control systems (ICS). ICSs can include supervisory control and data acquisition (SCADA) systems, distributed control systems (DCS), and other smaller control system configurations such as programmable logic controllers (PLC) often found in the industrial sectors and critical infrastructures. To guarantee the customer's privacy, the controllers may be designed to not store any historical use data in raw format or transfers consumption information of individual appliances to any third party outside the customer network. Moreover, to ensure the system security, strong algorithms can be used to encrypt the communication between the system's equipment.

FIG. 5 shows some aspects of an example implementation of the integrated roofing element 500 into a roof. The integrated roofing element can comprise an energy generation element 505 (e.g. a photovoltaic cell photovoltaic cell, diesel generator, wind turbine, thermoelectric device, piezoelectric device, and fuel cell), a microinverter (510 i.e. three-phase microinverter), an energy storage element 515 (i.e. a battery or a supercapacitor). The integrated roofing element 500 may be supported by both a structural component and a roof assembly structural component (not shown). The structural component can provide sufficient strength to the integrated roofing element such that one or more integrated roofing elements can span between support elements of a roof (not shown) without continuous solid support beneath each integrated roofing element. The roof assembly structural component can provide mechanical support to two or more integrated roofing elements in physical proximity to one or more walls of a building (not shown). Moreover, the structural component and a roof assembly structural component can allow the integrated roofing element 500 to tilt at an angle 550 with respect to a plane defining a frame that substantially encompasses the integrated roofing elements 500. Moreover, one end of the integrated roofing elements 500 can be operationally connected to a window 520, for example made of glass. The window can be opened 530 to provide ventilation. The integrated roofing elements 500 can be spaced apart from one another such that a working area 525 exists between the areas 540 defined by the integrated roofing element 500 having an angle 550 of approximately 0 degrees with respect to a plane defining a frame that substantially encompasses the integrated roofing elements 500.

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

Throughout this application, various publications may be referenced. The disclosures of these publications in their entireties are hereby incorporated by reference into this application in order to more fully describe the state of the art to which the methods and systems pertain.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

1. An integrated roofing element comprising:
an energy generation element;
electrical wiring and connections electrically coupled to the energy generation element; and
a structural component, the structural component being watertight and weathertight;
wherein the structural component provides sufficient strength to the integrated roofing element such that one or more integrated roofing elements can span between support elements of a roof without continuous solid support beneath each integrated roofing element, and
wherein the structural component comprises seals, said seals forming a watertight and weathertight connection between a first integrated roofing element and a second integrated roofing element when the first integrated roofing element is connected to the second integrated roofing element; the structural component further comprising a frame, the frame housing the energy generation element, the electrical wiring connections, and the seals; and
wherein the electrical connections are configured to electrically connect the first integrated roofing element to the second integrated roofing element.

2. The integrated roofing element of claim 1, wherein the energy generation element comprises one of a photovoltaic device, a photovoltaic-thermal device and a thermoelectric device.

3. (canceled)

4. (canceled)

5. (canceled)

6. The integrated roofing element of claim 1, further comprising, a DC to AC converter electrically coupled to the energy generation element, wherein the structural component comprises a frame, the frame housing the energy generation device, the DC to AC converter, and the electrical wiring and connections.

7. (canceled)

8. The integrated roofing element of claim 6, further comprising an energy storage element electrically coupled to the energy generation element, the frame housing the energy storage element, and wherein the energy storage element comprises at least one of a battery and a super-capacitor, and wherein the structural component comprises a frame, the frame housing the energy generation device, the energy storage element, and the electrical wiring and connections.

9. (canceled)

10. (canceled)

11. The integrated roofing element of claim 6, wherein the DC to AC converter comprises at least one of a single-phase DC to AC converter and a polyphase DC to AC converter.

12. (canceled)

13. (canceled)

14. (canceled)

15. The integrated roofing element of claim 8, wherein the integrated roofing element further comprises a rectifier,
wherein the rectifier is electrically connected to the electrical wiring and connections, and
wherein the rectifier is electrically connected to the energy storage element through the integrated roofing element controller.

16. A system comprising:
(a) a plurality of integrated roofing elements, each integrated roofing element comprising:
an energy generation device;
a;
electrical wiring and connections electrically coupled to the energy generation element; and
a structural component; and
the structural component being watertight and weathertight;
wherein the structural component provides sufficient strength to the integrated roofing element such that one or more integrated roofing elements can span between support elements of a roof without continuous solid support beneath each integrated roofing element,
wherein the structural component comprises seals, said seals forming a watertight and weathertight connection between a first integrated roofing element and a second integrated roofing element when the first integrated roofing element is connected to the second integrated roofing element; the structural component further comprising a frame, the frame housing the energy generation element, the electrical wiring connections, and the seals; and
wherein the electrical connections are configured to electrically connect the first integrated roofing element to the second integrated roofing element and
(b) a system controller in communication with an integrated roofing element controller provided on each of the plurality of integrated roofing elements;
wherein at least the first integrated roofing element of the plurality of integrated roofing elements being electrically connected to the second integrated roofing element of the plurality of integrated roofing elements via the connections of each of the plurality of integrated roofing elements to form a roof of a building.

17. The system of claim 16, wherein the energy generation element comprises one of a photovoltaic device, a photovoltaic-thermal device and a thermoelectric device.

18. The system of claim 16, further comprising an energy storage element, wherein the energy storage element comprises at least of a battery and a super-capacitor, and wherein the structural component comprises a frame, the frame housing the energy generation device, the energy storage element, and the electrical wiring and connections.

19. (canceled)

20. (canceled)

21. The system of claim 16, wherein at least one integrated roofing element of the plurality of integrated roofing elements includes a DC to AC converter, electrically coupled to the electrical wiring and connections, and wherein the structural component comprises a frame, the frame housing the energy generation device, the DC to AC converter, and the electrical wiring and connections.

22. The system of claim 21, wherein the DC to AC converter comprises one of a single phase micro-inverter and a polyphase microinverter.

23. (canceled)

24. (canceled)

25. The system of claim 18, wherein at least one integrated roofing element of the plurality of integrated roofing elements further comprises a rectifier,
wherein the rectifier is electrically connected to the electrical wiring and connections, and
wherein the integrated roofing element controller electrically connects the rectifier to the energy storage element.

26. (canceled)

27. (canceled)

28. (canceled)

29. (canceled)

30. The system of claim 16, wherein the system controller is in communication with a meter configured to measure energy flow between a remote power grid and the system.

31. (canceled)

32. The integrated roofing element of claim 1, further comprising a thermal regulation element.

33. The integrated roofing element of claim 32, wherein the thermal regulation element circulates a fluid within the roofing element.

34. The integrated roofing element of claim 32, wherein the thermal regulation element is one of an air gap separating the energy generation element from the energy storage element, and a fluid conduit disposed in the structural component.

35. The system of claim 16, wherein each integrated roofing element further comprises a thermal regulation element.

36. The system of claim 35, wherein the thermal regulation element circulates a fluid within the roofing element.

37. The system of claim 35, wherein the thermal regulation element wherein the thermal regulation element is one of an air gap separating the energy generation element from the energy storage element, and a fluid conduit disposed in the structural component.
